(19) United States
(12) Patent Application Publication
(10) Pub. No.: US 2020/0146186 A1
(43) Pub. Date: May 7, 2020

(54) MODULAR DATA CENTER WITH HORIZONTAL AIR FLOW

(71) Applicant: EdgePoint Systems LLC, Dallas, TX (US)

(72) Inventor: Mohamed Aboul Fotouh, Austin, TX (US)

(73) Assignee: EdgePoint Systems LLC

(21) Appl. No.: 16/676,223

(22) Filed: Nov. 6, 2019

Related U.S. Application Data
(60) Provisional application No. 62/756,415, filed on Nov. 6, 2018.

(51) Int. Cl. H05K 7/20

(52) U.S. Cl. CPC H05K 7/20736; H05K 7/20745; H05K 7/20754

(57) ABSTRACT

By utilizing a properly-sized horizontal cooling structure, the HVAC unit for a modular data center can support multiple modular data centers. A set of servers and other IT rack equipment mounted in the modular data center can be shipped to and then be operated at a site of the data center. A containment structure fabricated at a module assembly and factory site can contain the set of servers and other IT rack equipment. The HVAC unit mounted to the containment structure can direct an air flow within the containment structure in a horizontal flow cycle around the set of servers and other IT rack equipment. An air dam integrated into the containment structure directs blown supply air from the HVAC unit down a row of the servers and other IT rack equipment and sucks hot air on an opposite side of the row.

### RELATED APPLICATION

This application claims priority to and the benefit of under 35 USC 119 of U.S. provisional patent application titled “A Modular Data Center with Improvements,” filed Nov. 6, 2018, Ser. No. 62/756,415, which is incorporated herein by reference in its entirety.

### NOTICE OF COPYRIGHT

A portion of this disclosure contains material that is subject to copyright protection. The copyright owner has no objection to the facsimile reproduction by anyone of the material subject to copyright protection as it appears in the United States Patent & Trademark Office's patent file or records, but otherwise reserves all copyright rights whatsoever.

### FIELD

Embodiments of the design provided herein generally relate to a data center including a telecommunications data center. In an embodiment, a modular data center may have a side mounted air-cooling unit that creates a horizontal air flow in the modular data center.

### BACKGROUND

Information Technology (“IT”) operations are a crucial aspect of most organizational operations in the western world. One of the main concerns is business continuity. Companies rely on their information systems to run their operations. If a system becomes unavailable, company operations may be impaired or stopped completely. It is necessary to provide a reliable infrastructure and rapidly installed for IT operations, in order to minimize any chance of disruption. Information security is also a concern, and for this reason a datacenter has to offer a secure environment, which minimizes the chances of a security breach. A datacenter should therefore keep high standards for assuring the integrity and functionality of its hosted computer environment. Telcordia GR-3160, NEBS Requirements for Telecommunications Data Center Equipment and Spaces, provides guidelines for datacenter spaces within telecommunications networks, and environmental requirements for the equipment intended for installation in those spaces.

### SUMMARY

A modular data center can be designed to be physically combined with other modular data centers to a size determined by client use cases. By creating a horizontal air flow, the HVAC unit from one modular data center can support multiple modular data centers. A containment structure fabricated at a module assembly and factory site can contain a set of servers and other Information Technology rack equipment. The set of servers and other Information Technology rack equipment is mounted to the containment structure at an assembly and factory site. The HVAC unit mounted to the containment structure can direct an air flow within the containment structure in a horizontal flow cycle around the set of servers and other Information Technology rack equipment. An air dam integrated into the containment structure directs i) blown supply air from the HVAC unit down a row of the servers and other Information Technology rack equipment and ii) sucked hot air from the servers and other Information Technology rack equipment with the HVAC unit on an opposite side of the row. The modular data center, as assembled, with the HVAC unit attached to the end wall, is assembled as a shippable unit to a site of a data center as an integrated unit.

These and other features of the design provided herein can be better understood with reference to the drawings, description, and claims, all of which form the disclosure of this patent application.

### DRAWINGS

The drawings refer to some embodiments of the design provided herein in which:

FIG. 1 illustrates an embodiment of an exterior of a modular data center.

FIG. 2 illustrates an embodiment of a heating/ventilation/air-conditioning (HVAC) unit mounted to an end wall made of concrete of the containment structure to act as a cooling source to direct an air flow within the containment structure in a horizontal flow cycle around each row of servers and other Information Technology rack equipment.

FIG. 3 illustrates an embodiment of an end wall made of concrete cast with a supply air vent and a return air vent spaced in distance and size to match the HVAC unit.

FIG. 4 illustrates an embodiment of an entry wall and doorway of a modular data center.

FIG. 5 illustrates an embodiment of a containment structure.

FIG. 6a illustrates an embodiment of internal equipment for a modular data center.

FIG. 6b illustrates an embodiment of the air dam and the row of the servers and other Information Technology rack equipment forming a cold air aisle down a center of the containment structure for the blown supply air and a hot air aisle adjacent to an entry door and wall of the containment structure for the hot air being sucked back to the HVAC unit to reduce condensation forming within the containment structure when the entry door is opened.

FIG. 7 illustrates an embodiment of an exterior of an HVAC unit that is sealed to the end wall.

FIG. 8 illustrates a block diagram of an embodiment of the inner mechanics of an air-cooling unit

FIG. 9 illustrates an embodiment of an air flow within a data center megaplex.

FIG. 10 illustrates a block diagram of an embodiment of a cooling source.

FIG. 11 illustrates a block diagram of a mounted air-cooling unit including a heating coil to control humidity for the air flow within the containment structure.

FIG. 12 illustrates a flowchart of an embodiment of a method for fabricating a modular data center with a HVAC unit attached to a wall.

FIG. 13 illustrates a flowchart of an embodiment of a method for mounting a heating/ventilation/air-conditioning (HVAC) unit to a wall made of concrete of the containment structure to act as a cooling source to direct an air flow within the containment structure in a horizontal flow cycle.

FIG. 14 illustrates a flowchart of an embodiment of a method for operating a modular data center, where the modular data center, as assembled, with the HVAC unit attached to the end wall, is assembled as a shippable unit to a site of a data center as an integrated unit.

While the design is subject to various modifications, equivalents, and alternative forms, specific embodiments thereof have been shown by way of example in the drawings and will now be described in detail. It should be understood that the design is not limited to the particular embodiments disclosed, but—on the contrary—the intention is to cover all modifications, equivalents, and alternative forms using the specific embodiments.

### DESCRIPTION

In the following description, numerous specific details are set forth, such as examples of specific data signals, named components, number of servers in a system, etc., in order to provide a thorough understanding of the present design. It will be apparent, however, to one of ordinary skill in the art that the present design can be practiced without these specific details. In other instances, well known components or methods have not been described in detail but rather in a block diagram in order to avoid unnecessarily obscuring the invention. Thus, the specific details set forth are merely examples. The specific details may be varied from and still be within the spirit and scope of the invention. Example processes for and apparatuses to manage cooling for a datacenter facility are described. The following drawings and text describe various example implementations of the design.

A fabricator can build an entire modular data center at a module assembly and factory site. The fabricator can then ship that modular data center to a site of the data center. A data center operator at that site can then connect that modular data center to any power supply or data transmission media available at that site of the data center. A data center operator is a manager or agent of the manager in charge of operating the data center at the site of the data center. This provides the data center with a plug-and-play capability not normally present in this type of equipment. Depending on the needs of the data center operator, one or more modular data centers may be joined and abutted into a data center megaplex to increase computing power. A data center megaplex as used herein refers to a data center comprised of multiple modular data centers.

The modular data center as used herein conveys an entire modular data center that ships on the road preinstalled with IT racks of computing equipment, electrical distribution system and uninterruptible power supply (UPS) batteries, and a heating/ventilation/air-conditioning (HVAC) system. Thus, a fabricator can ship a modular data center on the road as an integrated unit. The modular data center includes a prefabricated telecommunications data center or other data center that is designed in a modular fashion.

The modular data center can accommodate any design of IT computing equipment racks that include servers, databases, etc. of varying size and manufacturer. The IT computing equipment racks can have varying depths and clearances for the racks, which all can still be installed in the modular data center. The IT racks can be a heterogeneous mix of IT racks from different manufactures. As the containment structure for the modular data center is a formed concrete structure, rather than a modified rail car, the fabricator can adjust the size of the modular data center based on the size of the IT computing equipment selected. The only limit is the shipping load limit.

The air containment system includes one or more HVAC units coupled to the concrete sidewalls of the modular data center, an air filter frame, air plenums cast in the concrete sidewalls, a free air flow design through the aisles of the modular data center, and a dividing wall/air dam. The containment air supply, air conditioning, and air-cooling system divide the modular data center into hot and cold aisles. A dividing wall in the shell acts as an air dam to separate hot and cold air plenums in the building. The air containment system with the dividing wall provides a barrier between the hot and cold air plenums in the container building. The HVAC units specifically work with the dividing wall to return hot air thorough the sidewalls of the shell on one side of the wall and supply cold air through the sidewall of the other side of the wall.

An HVAC cooling unit couples to the side wall of the containment building. The HVAC units are specifically configured structurally to work with the wall to supply air on the rear and suck air on the front. Thus, the system does not supply air to the bottom of the container and then suck returned hot air from the top of the container building. The HVAC cooling units are built and constructed to match the air flow pattern for supplying the free-flowing air into the cold aisle of the data floor and sucking hot free flowing air from the hot aisle of the data floor. The HVAC unit is built with multiple compartments. One compartment uses positive pressure to blow cooled free flowing air. The other compartment uses negative pressure to suck the hot air and route the hot air into the compressor to cool that air.

Again, the HVAC cooling unit couples to the side wall of the containment building. The frame that supports the supply and return filters can be built into the sidewalls. Also, this HVAC unit does not use ducting to direct the flow of air through the modular data center. Rather, the HVAC unit uses free flowing air to blow in the cold air from the sidewall. The HVAC unit then uses the dividing wall to act as a damper separator. The HVAC unit then returns the hot air through the free flow of air to the sidewall on the return side.

The HVAC system does not use heat exchangers. Rather, the system uses a compressor that is set in capacity to be a whole room cooler at twice the maximum IT power load. Thus, the HVAC unit is sized in capacity to be able to cool an expected heat load of at least twice the maximum IT power load for a single data floor.

The HVAC system for the modular data center supports a wide range of external temperature and humidity. The HVAC system is not merely exchanging the hot air inside the modular data center with the external air. Instead, the whole room HVAC system is a self-contained air-cooling system that uses compression coolers to cool the internal air in the modular data center. This keeps the internal air in the modular data center cleaner than exchanging with outside air and with less moisture than exchanging with external air. The modular data center may be in geographic areas with a far greater range of humidity and temperature conditions since the system uses the whole room HVAC unit to internally cool the air being circulated in the modular data center. Again, the HVAC units used compressor cooling, rather than exchanging heat with the outside air.

A fabricator may assemble a modular data center at the module assembly and factory site. The fabricator can mount a set of servers and other Information Technology rack equipment in the modular data center at the module assembly and factory site. The fabricator may ship the modular data center to a data center operator at a site of the data center. The data center operator can then operate the set of servers and other Information Technology rack equipment as a data center at the site of the data center. If a single modular data center does not provide enough computing power for the data center operator's needs, the data center operator can connect the modular data center with an expansion modular data center to create a data center megaplex of merged modular data centers at the site of the data center.

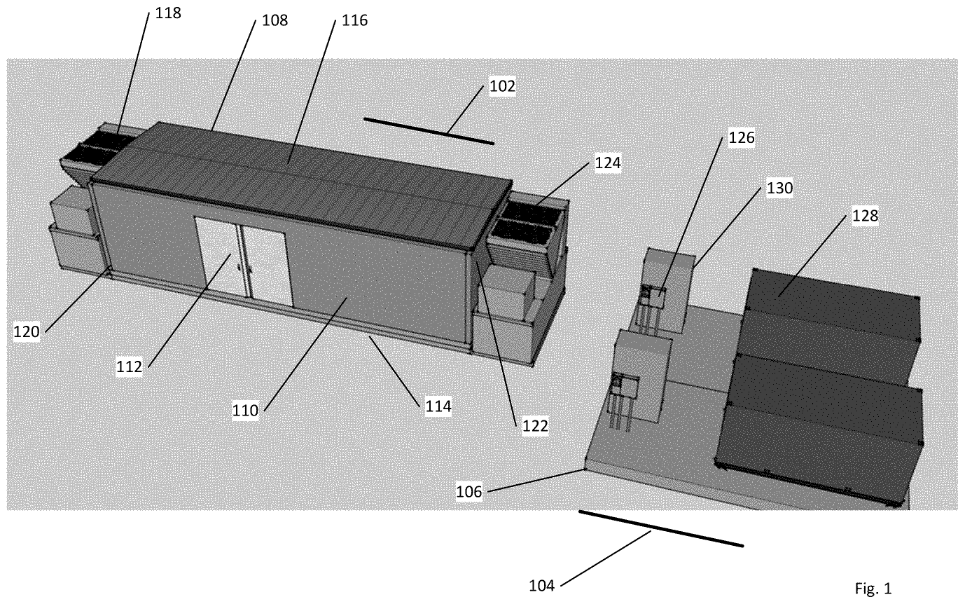

FIG. 1 illustrates an embodiment of an exterior of a single modular data center. The modular data center can have a containment building 102 to contain a set of servers and other Information Technology rack equipment that perform the data operations. The modular data center can have a power center 104 to manage the power supply to the data center. The power center 104 can be mounted to the containment structure 102 or established near the containment building on a concrete skid 106.

The containment structure 102 may have a pre-cast concrete shell 108 with a front wall 110. The front wall 110 may have a door 112 to access the containment structure 102. The concrete shell 108 may be rated to withstand winds exceeding 150 miles per hour. The concrete shell 108 may have a floor 114, a roof 116 over the floor 114, and two end walls connected to the floor, creating a shell opening. A HVAC unit 118 can be mounted to an end wall to provide a cooling source of air. The HVAC unit 118 may provide enough cooling to support double the number of data servers in the set of servers and other Information Technology rack equipment. The other end wall near the power center can be used to route electrical power from the power supply 122. A backup HVAC unit 124 may be attached to the wall if the primary HVAC unit 118 fails.

The power center 104 may have a utility meter 126 to measure incoming power consumed and its associated circuit breaker to provide a point of disconnect in a time of emergency. The power center 104 may have a backup generator 128 to provide power during a power failure. The power center 104 may have an automatic transfer switchgear 130 to switch from an exterior power source to the backup generator 128.

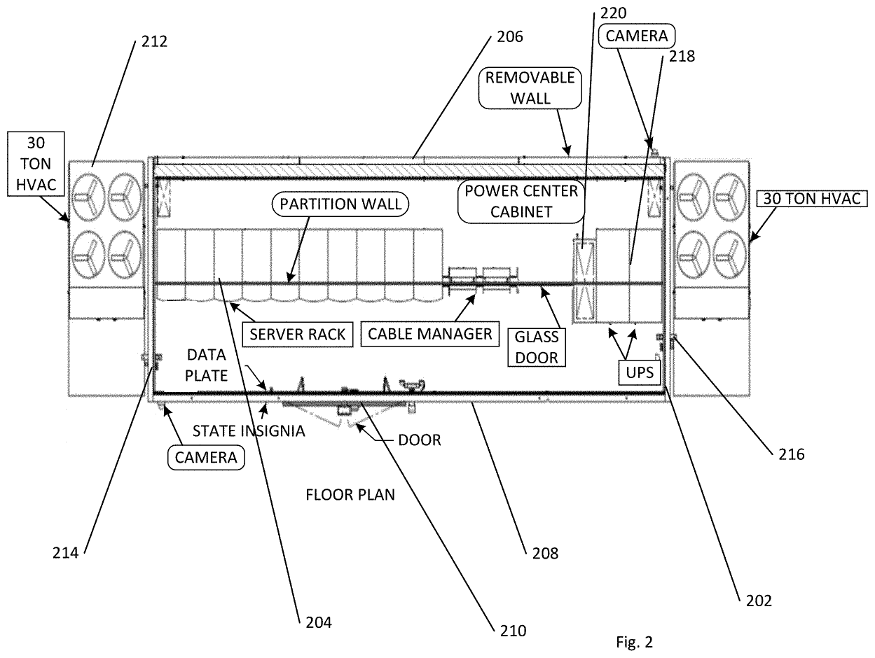

FIG. 2 illustrates an embodiment of an interior of a heating/ventilation/air-conditioning (HVAC) unit mounted to an end wall made of concrete of the containment structure to act as a cooling source to direct an air flow within the containment structure in a horizontal flow cycle around each row of servers and other Information Technology rack equipment. The concrete shell 202 may contain a set of servers and other Information Technology rack equipment 204 mounted in the shell 202 to perform data center operations. The set of servers and other Information Technology rack equipment 204 may be mounted to the floor in a row structure on the interior of the shell 202.

The shell 202 may have an end wall attached to a cooling source 212. The cooling source 212 may have a HVAC unit 214 to control the air temperature of the modular data center. A wall 216 may have a power unit 218 mounted to the wall 216 to provide an uninterruptible power source. The power unit 218 may direct power through a power center cabinet 220 to provide a control system for the power unit 218.

The shell 202 may have a shell opening created by the floor, two end walls, and the roof. A removable side wall 206 may cover the shell opening. The removable side wall 206 can be attached to the shell 202 via a structural connector. The removable side wall 208 may be a rear wall opposite a front entry wall 208. The front entry wall 208 may have a door 210 for entering the modular data center.

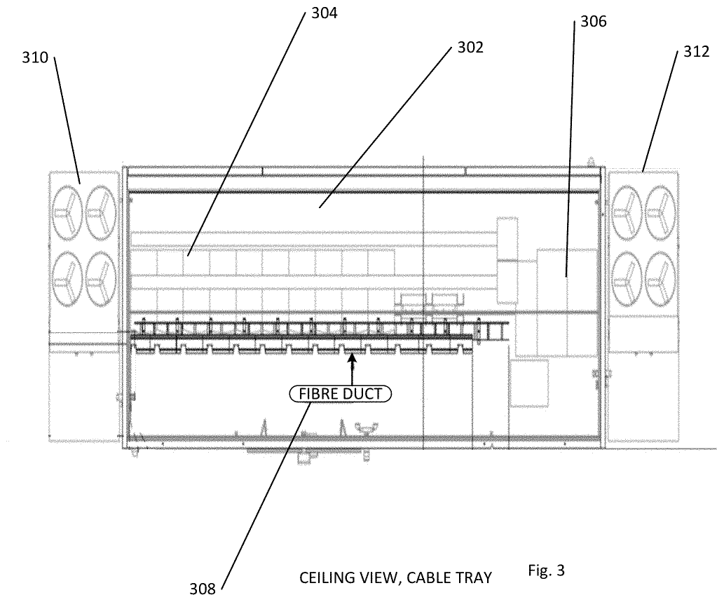

FIG. 3 illustrates an embodiment of an end wall made of concrete cast with a supply air vent and a return air vent spaced in distance and size to match the HVAC unit. The modular data center may have a roof 302 to shelter the set of servers and other Information Technology rack equipment 304. The modular data center may have a power unit 306 to supply power for the set of servers and other Information Technology rack equipment 304. The modular data center may have one or more electrical conduits or busways 308 routed along i) the ceiling or ii) the floor or iii) both to connect the set of servers and other Information Technology rack equipment 304 to the power unit 306. The modular data center 302 may have a HVAC unit 310 to control the air temperature and humidity of the modular data center 302. The modular data center 302 may have a backup HVAC unit 312 should the primary HVAC unit 310 fail.

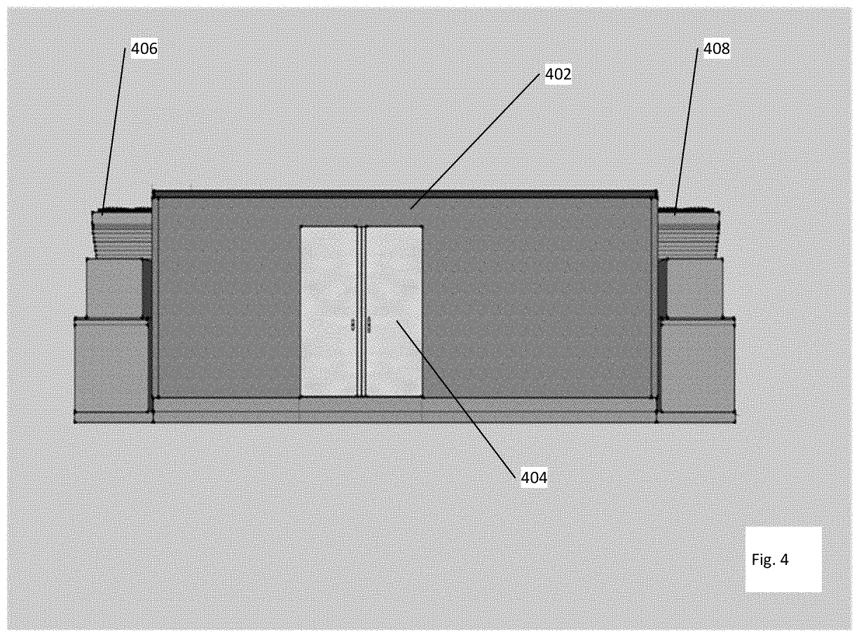

FIG. 4 illustrates an embodiment of an entry wall of a modular data center. The modular data center may have an entry wall 402 with a door 404 to allow access to the modular data center. Generally, the rear wall is to be the wall removed when combining modules. If a third module is being added, then a data center operator can remove the entry wall 402 to connect the original modular data center to a rear shell opening for the third modular data center.

The modular data center may have a HVAC unit 406 to control the air temperature and humidity of the modular data center. The HVAC unit 406 can be installed to have the capacity to cool twice the number of data servers in the set of servers and other Information Technology rack equipment of the modular data center. The modular data center may have a backup HVAC unit 408 should the primary HVAC unit 406 fail.

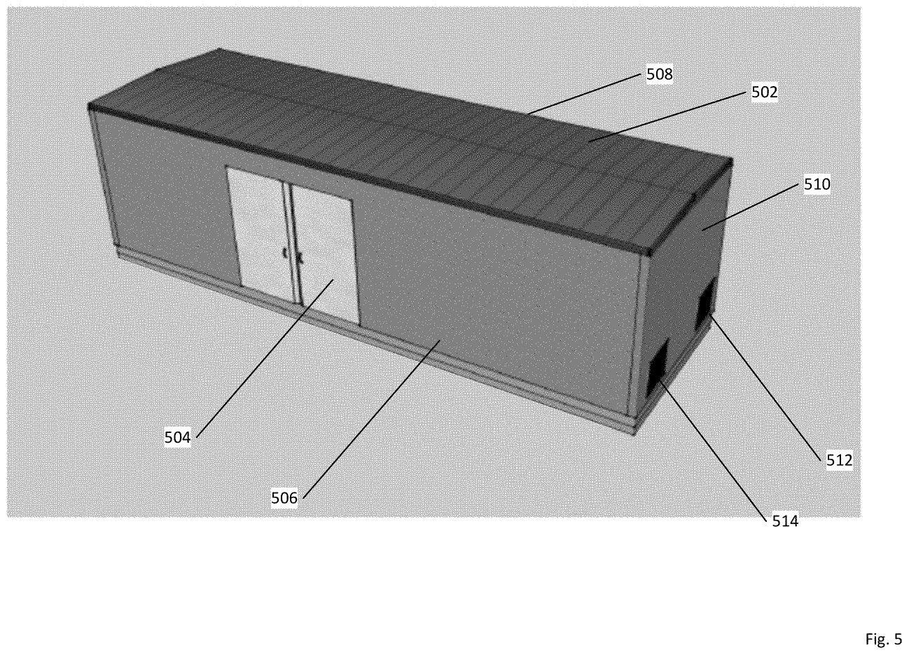

FIG. 5 illustrates an embodiment of a containment structure. The containment structure 502 may have a door 504 on an entry wall 506 to allow a data center operator to enter the modular data center. A rear wall 508 of the containment structure 502 may be opposite the entry wall 506. A HVAC unit may be mounted to a cooling source 510 of the containment structure 502. The cooling source 510 may have a supply air vent 512 and a return air vent 514. The supply air vent 512 may be close to the rear wall 508, so that the HVAC unit creates a cold air aisle adjacent to the rear wall 508. The return air vent 514 may be close to the entry wall 506, so that the HVAC unit creates a hot air aisle adjacent to the entry wall 506. Thus, if the data center operator enters the containment structure 502, any new moisture added to the air does not immediately condense into water inside the containment structure 502 because of the cold air.

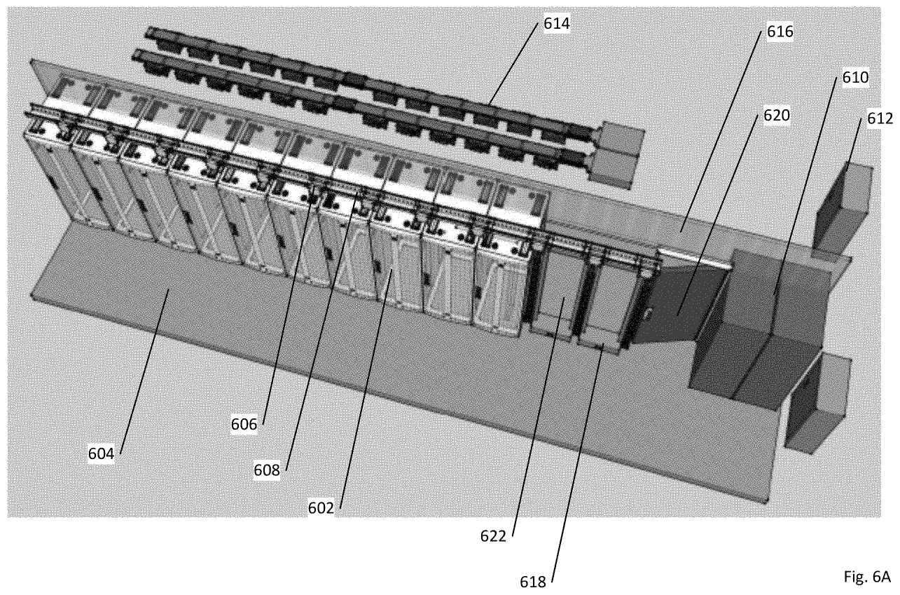

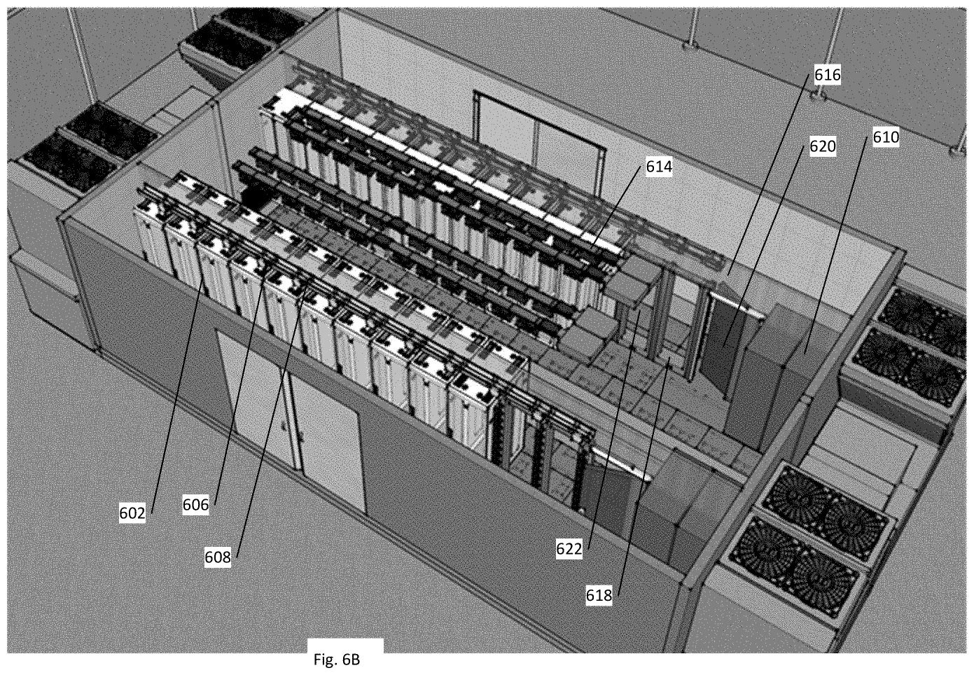

FIG. 6a illustrates an embodiment of internal equipment for a modular data center. The modular data center may have a set of servers and other Information Technology rack equipment 602 mounted to the floor 604 of the containment structure in a data server rack 606. An overhead tray 608 attached to the top of the data server rack 606 may carry fiber to allow data to be transmitted between the set of servers and other Information Technology rack equipment 602 and an outside data connection.

The modular data center may have an uninterruptible power supply 610 mounted to the floor 604 of the containment structure opposite the set of servers and other Information Technology rack equipment 602 near the power supply wall. An electrical panel 612 mounted on the power supply wall can control the power supply to the modular data center. An overhead busway 614 can supply power from the power supply, either from the uninterruptible power supply 610 or a local utility, to the set of servers and other Information Technology rack equipment 602.

The modular data center can have an air dam 616 integrated into the containment structure to create a supply air aisle and a return air aisle on either side of the set of servers and other Information Technology rack equipment 602. The air dam 616 can create a supply air aisle from the air-cooling unit to the set of servers and other Information Technology rack equipment 602, generally adjacent to the rear wall of the containment structure. The air dam 616 can create a return air aisle from the set of servers and other Information Technology rack equipment 602 to the air-cooling unit, generally adjacent to the entry wall of the containment structure. The air dam 616 can have data server cutouts 618 into the air dam to accommodate the set of servers and other Information Technology rack equipment 602. The modular data center can use a blocking panel 620 to prevent airflow through an unused data server cutout 618. The air dam 616 can have a gap 622 at the end to allow the air to transition from the supply air aisle to the return air aisle. The gap 622 can have a filter to remove particulates from the supply air aisle from the reaching the return air aisle.

FIG. 6b illustrates an embodiment of the air dam 616 and the row of the servers and other Information Technology rack equipment 602 forming a cold air aisle down a center of the containment structure for the blown supply air and a hot air aisle adjacent to an entry door and wall of the containment structure for the hot air being sucked back to the HVAC unit. The hot air aisle adjacent to the entry door reduces condensation forming within the containment structure when the entry door is opened.

The HVAC units can have a compressor specifically configured structurally to work with the end wall to have a positive pressure compartment to supply air on one side of the HVAC unit and a negative pressure compartment to suck air on the other side of the HVAC unit.

The end wall made of concrete can be cast with an indentation to receive at least a portion of HVAC unit into the end wall itself.

The HVAC unit can have a compression cooler that is set in capacity to be a whole room cooler at twice a maximum IT power load of the servers and other Information Technology rack equipment 602; and thus, the HVAC unit is sized in capacity to be able to cool an expected heat load of at least twice the maximum IT power load.

The height and width dimensions from wall to wall and floor to ceiling have been specifically chosen. The servers and other Information Technology rack equipment can have a heterogeneous mix of servers and IT rack equipment from a plurality of manufactures. The dimensions of the containment structure can be based on a maximum estimated dimensions of a tallest and widest expected servers and other Information Technology rack equipment in order to accommodate the heterogeneous mix of servers and IT rack equipment from the plurality of manufactures.

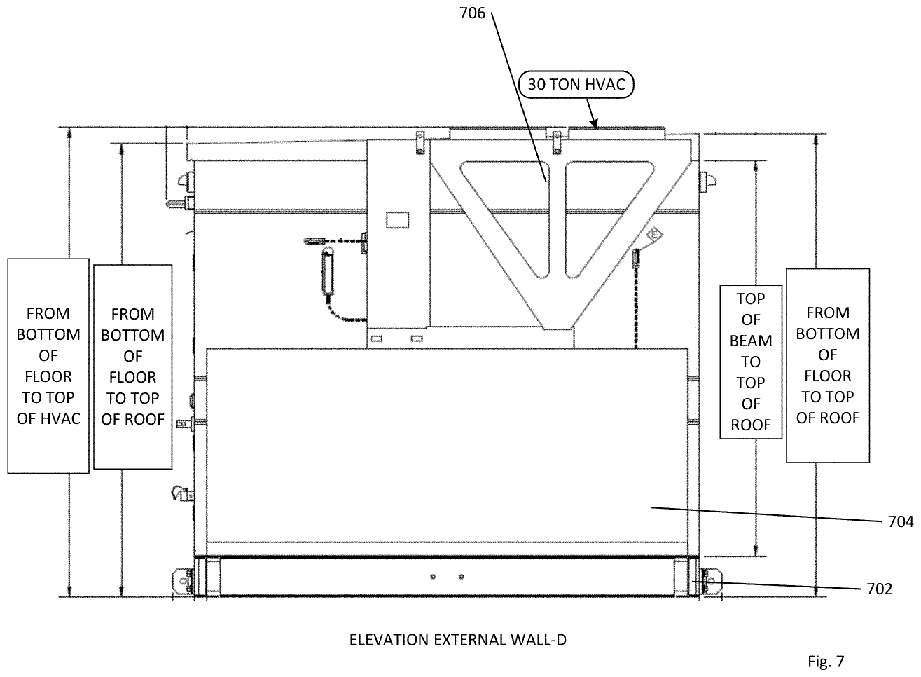

FIG. 7 illustrates an embodiment of an exterior of a HVAC unit that is sealed to the end wall. The HVAC unit can have a mounting structure 702 to attach the air-cooling unit as the cooling source. The HVAC unit can have a housing unit 704 to cover the duct work taking in the hot air and producing cool air to be pumped into the modular data center. The HVAC unit can have a fan system 706 to cool off the air as the air flow travels through the air-cooling unit. The fan system 706 can cool off the ducts and the air within without exchanging the air of the containment structure with external air, maintaining a hermetically contained atmosphere.

The HVAC unit may have a first metal sleeve inserted from within the containment structure into the HVAC unit through the supply air vent to act as a supply sleeve through the end wall. The HVAC unit may have a second metal sleeve inserted from within the containment structure into the HVAC unit through the return air vent to act as a return sleeve through the end wall. The supply sleeve and the return sleeve are sealed at the connections to the concrete cast supply air vent and the return air vent where they abut to the HVAC unit as well as the HVAC unit is sealed to the end wall.

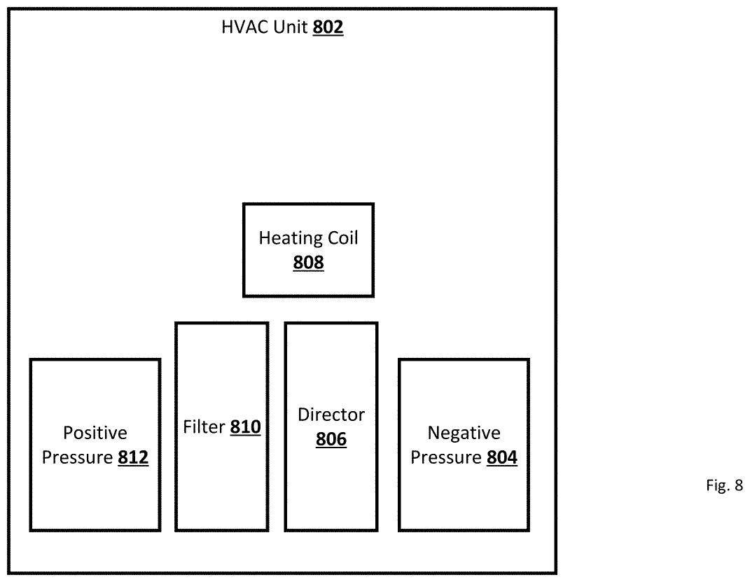

FIG. 8 illustrates a block diagram of an embodiment of the inner mechanics of an air-cooling unit. The air-cooling unit can have a HVAC unit 802. The HVAC unit 802 can have a negative pressure compartment 804 to suck in air from the return air aisle via a return vent in the containment structure. The HVAC unit 802 can move the air flow through an air director 806 so that the air director sucks air from the hot air aisle and blows air to the cold air aisle. The air director 806 can be a fan, a turbine, or a bladeless inline fan. The HVAC unit 802 can use a heating coil 808 or a compressor integrated into the air-cooling unit to control the humidity for the air flow and to cool the air flow. The air director 806 can move the air flow through an air filter 810 to remove particulates from the air flow. The HVAC unit 802 can have a positive pressure chamber 812 to blow cold air into the supply air aisle via a supply vent of the containment structure. The positive chamber is level with the negative chamber to facilitate a horizontal flow around the set of servers and other Information Technology rack equipment within the containment structure.

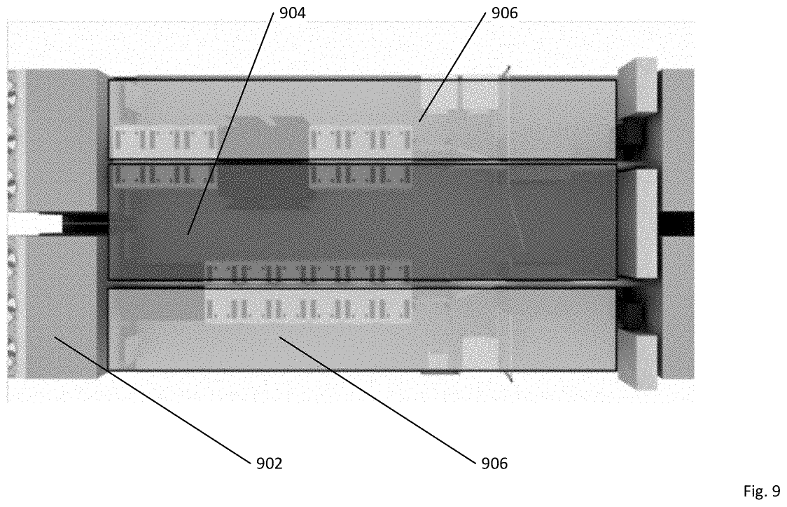

FIG. 9 illustrates an embodiment of an air flow within a data center megaplex. The data center megaplex has a central aisle between two sets of servers and other Information Technology rack equipment, with a door on entry walls on both sides of the combined containment structure. The air-cooling unit 902 can blow supply air in a cold air aisle 904 down the center aisle. A hot air aisle 906 returns the heated air from the servers and other IT equipment to the air-cooling unit on either side of the cold air aisle 904 adjacent to the two entry walls.

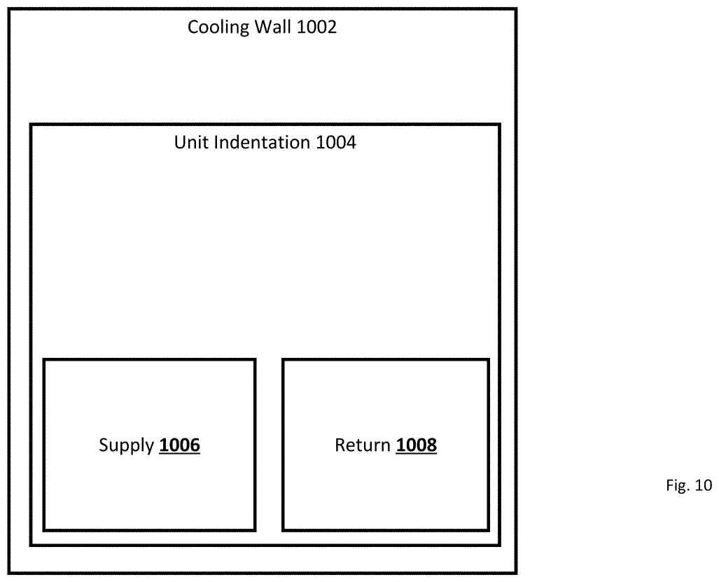

FIG. 10 illustrates a block diagram of an embodiment of a cooling source. The fabricator can cast the concrete wall 1002 with an indentation 1004 shaped to fit the air-cooling unit. The fabricator can also cast the cooling source with a supply vent 1006 and a return vent 1008.

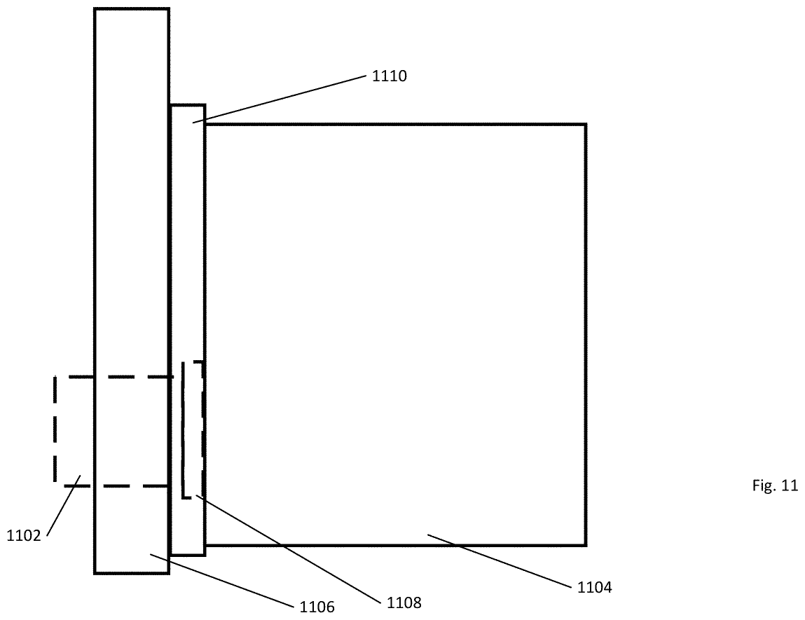

FIG. 11 illustrates a block diagram of a mounted air-cooling unit including a heating coil to control humidity for the air flow within the containment structure. The fabricator can insert a metal sleeve 1102 from within the containment structure into the air-cooling unit 1104 through a vent in the cooling source 1106. The fabricator can seal 1108 the sleeve 1102 to the air-cooling unit 1104. The fabricator can seal 1110 the air-cooling unit 1104 to the cooling source 1106 to provide a second layer of protection and insulation.

The system is designed for an initial set of one or more modular data centers that may readily connect to other modular data centers at a future date of operation of the overall site via a side wall removable from the rest of the shell of the modular data center. Further, the electrical and HVAC systems acting as a data center electrical infrastructure support a maximum load of IT racks per modular data center.

The IT rack computer room, the electrical distribution room, and the HVAC system all ship as one integrated unit. Due to the prefabrication, there is no need to interconnect these three components in the field at the construction site because they were shipped and manufactured as an integrated unit. Note, when a modular data center ships, this unit stays below the super load limit. Thus, the modular data center is constructed to stay below the super load limit of 100,000 pounds and 12-foot width for shipping freight.

The modular data center is designed to allow the removal of one or multiple sections of a wall, or even removal of an entire wall. The modular data center is designed to allow an expansion modular data center to be placed in direct adjacency to an initial modular data center. As each modular data center is made to join and interlock with other modular data centers, certain adjustments are made to the structure of the containment structure, the layout of the data center electrical infrastructure, and the design of the HVAC system to accommodate modular growth.

In the modular data center, the construction and design facilitate the removal of the concrete wall, reinforced with iron rebar and made lighter with foam inserts. A data center operator may remove even merely sections of the wall at some later date past the initial construction of the modular data center without interrupting the operations of the existing IT racks in the modular data center. In removing the wall, the wall can be picked up and out of the modular data center to expand the floor space for IT racks of equipment in the future.

With the removable wall removed, a first modular data center can interconnect with a second modular data center with its removable wall removed to double the floor space for IT racks. Thus, the IT racks of servers from the initial modular data center are integrated with the server racks and IT equipment from the expansion modular data center on the same data floor. In addition, a third or more modular data centers may interconnect with other modular data centers with the removable wall or just sections of removable wall removed to combine floor space for servers and other IT racks in connected modular data centers.

The removable wall is made of a concrete base with limited attachments to the shell of the modular data center, as well as any internal data center infrastructure and equipment mountings, in order to make the wall easily removable. Each wall has one or more connection points to the end wall, roof, and/or floor as well as a lift mechanism built into the wall to allow the wall to be lifted and set in place by an industrial device. For example, the wall can have one or more forklift cutouts to receive the prongs of a forklift. Alternately, the wall can have a crane hook attachment to interface with a crane. Also, the walls can be connected via bolts and brackets that can be loosened to allow the wall to be removed, as opposed to using concrete anchors to secure the wall to the other walls and foundation of a modular data center. Thus, in an embodiment, both side walls can be constructed as removable walls made of concrete with connection points for large object handling machinery. The side walls can be secured in place by brackets and bolts.

Also, no critical infrastructure runs along the side of the removable wall. No panels or other structures are mounted to the removable wall. Instead, any panels and structures are mounted to the shell, which includes the two fixed side walls, the floor, and the ceiling. This leaves the removable wall with no critical structure attached to the removable wall, rendering the wall more readily removable.

The pipes and electrical conduit are supported by connections to the floor, ceiling, or the other two fixed walls. Thus, the support structures for the equipment and infrastructure are supported from shell, and not from either of the removable walls of the modular data center.

The modular data center uses steel reinforced concrete walls and ceilings, and concrete or cinder block floors verses steel shipping containers. The features for each reinforced wall, such as the filter space and air plenum, are cast in place during fabrication. Similarly, the foundation has specific stub ups for the conduits. The removable wall is designed to allow expansion of the IT rack space in the future, and to have no permanent attachments to other equipment in the modular data center to that removable wall as a support structure for that equipment installed in the modular data center. In an embodiment, the walls may be made of other materials than concrete based materials.

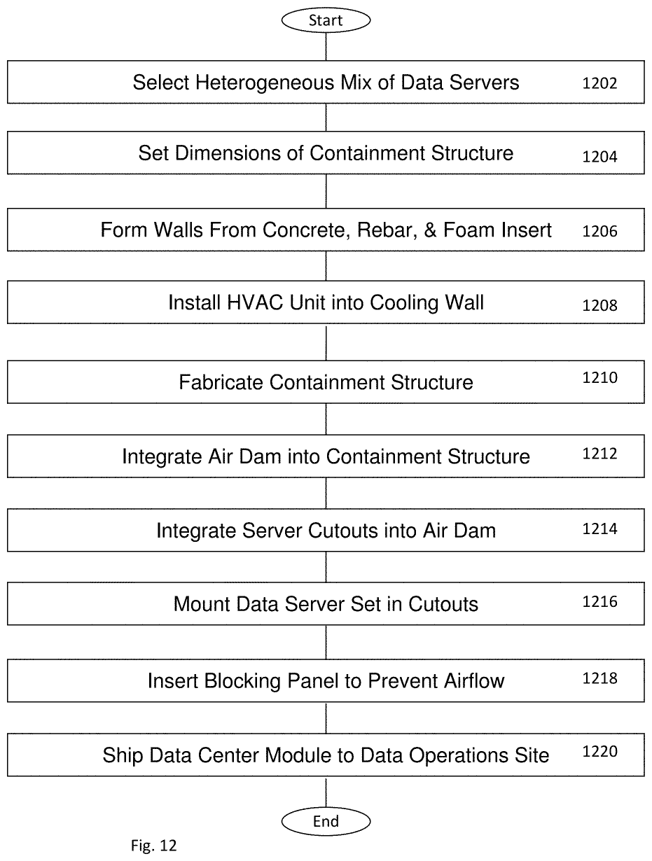

FIG. 12 illustrates a flowchart of an embodiment of a method for fabricating a modular data center. A fabricator can select a heterogeneous mix of data servers for the set of servers and other Information Technology rack equipment (Block 1202). The fabricator can set the dimensions of the containment structure based on the dimensions of the set of servers and other Information Technology rack equipment (Block 1204). The dimensions of the containment structure can be based on a maximum estimated dimensions of a tallest and widest expected servers and other Information Technology rack equipment available on the market in order to accommodate the heterogeneous mix of servers and IT rack equipment from the plurality of manufactures.

The fabricator can form the walls of the containment structure from concrete with an internal structure having metal rebar for structure support and foam inserts to reduce the weight of the structure (Block 1206). The fabricator can install a HVAC unit into the wall of the containment structure to provide cooling air (Block 1208). The fabricator can fabricate a containment structure for the modular data center, with the HVAC unit, and the servers and IT equipment, all assembled at a module assembly and factory site (Block 1210). The fabricator can integrate an air dam into the containment structure to create a supply air aisle from the air-cooling unit to the set of servers and other Information Technology rack equipment and a return air aisle from the set of servers and other Information Technology rack equipment to the air-cooling unit (Block 1212). The fabricator can create an air dam to accommodate the set of servers and other Information Technology rack equipment (Block 1214). The fabricator can mount the set of servers and other Information Technology rack equipment into the air dam (Block 1216). The fabricator can insert blocking panels into unused data server cutouts to prevent airflow through the unused data server cutouts (Block 1218). The fabricator can ship the completed modular data center to a site of the data center (Block 1220).

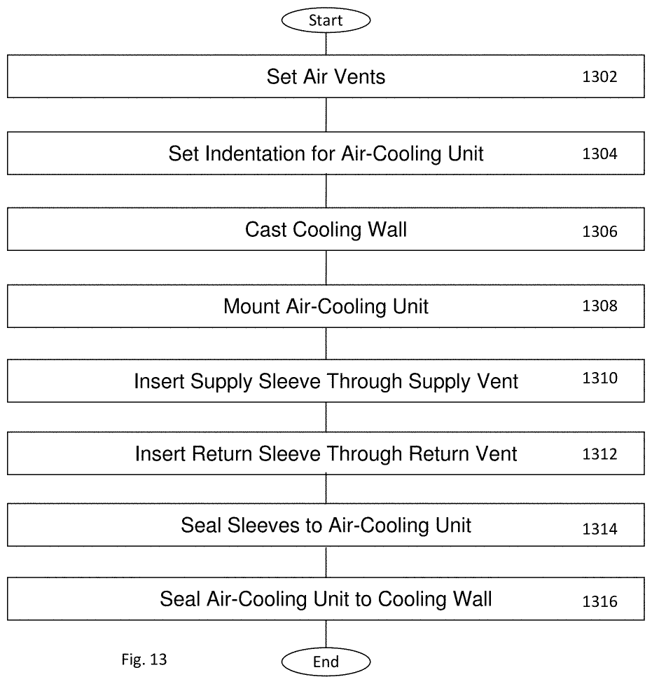

FIG. 13 illustrates a flowchart of an embodiment of a method for mounting a heating/ventilation/air-conditioning (HVAC) unit to an end wall made of concrete of the containment structure to act as a cooling source to direct an air flow within the containment structure in a horizontal flow cycle. The fabricator can set a supply air vent and a return air vent for the air-cooling unit in an end wall made of concrete of the containment structure to provide a cooling air (Block 1302). The fabricator can set an indentation for the HVAC unit in the wall (Block 1304). The fabricator can also cast an air plenum in the wall (Block 1306). The fabricator can mount the HVAC unit as the cooling source (Block 1308). The fabricator can insert a first metal sleeve from within the containment structure into the air-cooling unit through the supply air vent to act as a supply sleeve (Block 1310). The fabricator can insert a second metal sleeve from within the containment structure into the air-cooling unit through the return air vent to act as a return sleeve (Block 1312). The fabricator can seal the supply sleeve and the return sleeve to the air-cooling unit (Block 1314). The fabricator can seal the air-cooling unit to the cooling source to provide a second layer of protection and insulation for the cooling air (Block 1316).

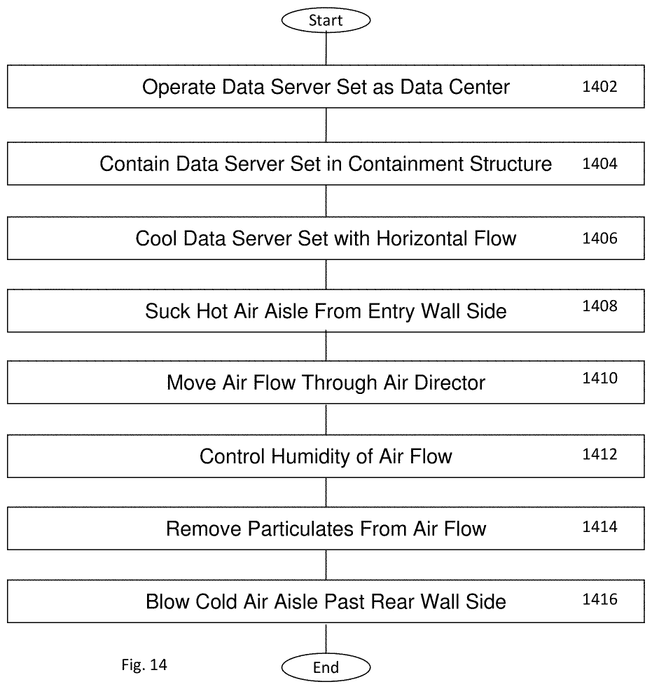

FIG. 14 illustrates a flowchart of an embodiment of a method for operating a modular data center. The modular data center can operate a set of servers and other Information Technology rack equipment as a data center at a site of the data center (Block 1402). The modular data center can contain the set of servers and other Information Technology rack equipment in a containment structure, wiring, piping, and HVAC unit, all assembled at a module assembly and factory site (Block 1404). The modular data center can cool the set of servers and other Information Technology rack equipment using the HVAC unit to direct an air flow in a horizontal flow cycle around the set of servers and other Information Technology rack equipment (Block 1406).

The modular data center can use a heating/ventilation/air-conditioning unit mounted to the containment structure to act as the air-cooling unit. The air-cooling unit can suck hot air past the set of servers and other Information Technology rack equipment adjacent to the entry wall side (Block 1408). The air-cooling unit can move the air flow through an air director so that the air director sucks air from the hot air aisle (1410). The air-cooling unit can control the humidity for the air flow with a heating coil and/or a compressor integrated into the air-cooling unit (Block 1412). The air-cooling unit can remove particulates from the air flow with an air filter integrated into the air-cooling unit (Block 1414). The air-cooling unit can direct the air flow to blow a cold air past the set of servers and other Information Technology rack equipment on the opposite side (Block 1416).

While some specific embodiments of the design have been shown, the design is not to be limited to these embodiments. The design is to be understood as not limited by the specific embodiments described herein, but only by the scope of the appended claims. Moreover, specific components and various embodiments have been shown and described. It should be understood that the invention covers any combination, sub-combination, or re-combination, including duplicating components, subtracting components, combination components, integrating components, separating components, and/or dividing components.

The terms “approximately” and “about” are used interchangeably to indicate that the disclosed and suggested values do not require exact precision. The relative inclusions of values around each value depends on the error in building, manufacturing, and installing the components, as is generally practiced by a person of skill in the art. Even without the specific identification of approximation (i.e. the term “about” or “approximate”), all of the dimensions disclosed are examples only and include equivalent or approximate values to the stated value to achieve similar, equal, or better benefits or effects to those of the disclosed dimensions. “Majority” is understood to be more than 50% of the floor area, while “substantial” is understood to be at least more than 75% of the floor and preferably more than 85% of the floor area.

What is claimed is:

1. A prefabricated modular data center, comprising:
a containment structure of the modular data center formed at an assembly and factory site by assembling at least a floor, a roof over the floor, and two end walls connected to the floor and roof;
a set of servers and other Information Technology rack equipment mounted to the floor in the shell;
a heating/ventilation/air-conditioning (HVAC) unit mounted to a first end wall of the containment structure to act as a cooling source to direct an air flow within the containment structure in a horizontal flow cycle around each row of servers and other Information Technology rack equipment, where the first end wall has an opening through the first end wall for the HVAC unit; and
an air dam integrated into the containment structure configured to direct blown supply air from the HVAC unit down a row of the servers and other Information Technology rack equipment and suck hot air from the servers and other Information Technology rack equipment with the HVAC unit on an opposite side of the row, where the modular data center, as assembled, with the HVAC unit attached to the end wall, is assembled as a shippable unit to a site of a data center as an integrated unit.

2. The prefabricated modular data center of claim 1, wherein the air dam and the row of the servers and other Information Technology rack equipment form i) a cold air aisle down a center of the containment structure for the blown supply air and ii) a hot air aisle adjacent to an entry door and wall of the containment structure for the hot air being sucked back to the HVAC unit to reduce condensation forming within the containment structure when the entry door is opened.

3. The prefabricated modular data center of claim 1, wherein the first end wall is made of concrete and cast with a supply air vent and a return air vent spaced in distance and size to match the HVAC unit.

4. The prefabricated modular data center of claim 3, further comprising:
a first metal sleeve inserted from within the containment structure into the HVAC unit through the supply air vent to act as a supply sleeve through the first end wall; and
a second metal sleeve inserted from within the containment structure into the HVAC unit through the return air vent to act as a return sleeve through the first end wall.

5. The prefabricated modular data center of claim 4, wherein the supply sleeve and the return sleeve are sealed at their connections to the concrete cast supply air vent and the return air vent where they abut to the HVAC unit, as well as the HVAC unit is sealed to the first end wall.

6. The prefabricated modular data center of claim 1, wherein the first end wall made of concrete is cast with an indentation to receive at least a portion of HVAC unit into the first end wall itself.

7. The prefabricated modular data center of claim 1, wherein the HVAC units has a compressor structurally configured to work with the first end wall to have a positive pressure compartment to supply air on one side of the HVAC unit and a negative pressure compartment to suck air on the other side of the HVAC unit.

8. The prefabricated modular data center of claim 1, wherein the HVAC unit has a compression cooler that is set in capacity to be a whole room cooler at twice a maximum IT power load of the servers and other Information Technology rack equipment; and thus, the HVAC unit is sized in capacity to be able to cool an expected heat load of at least twice the maximum IT power load.

9. The prefabricated modular data center of claim 8, further comprising:
a dehumidifier cooperating with the HVAC unit, where the compression cooler does not exchange internal air in the modular data center with outside air; and thus, is configured to create a self-contained air cooling system that minimizes an amount moisture present in air being cooled by the compression cooler and subsequently supplied to the servers and other Information Technology rack equipment.

10. The prefabricated modular data center of claim 8, wherein the servers and other Information Technology rack equipment has a heterogeneous mix of servers and IT rack equipment from a plurality of manufactures.

11. The prefabricated modular data center of claim 10, wherein dimensions of the containment structure are based on a maximum estimated dimensions of a tallest and widest expected servers and other Information Technology rack equipment in order to accommodate the heterogeneous mix of servers and IT rack equipment from the plurality of manufactures.

12. A method for a module data center, comprising:
operating a set of servers and other Information Technology rack equipment in a modular data center as a data center at a data center site;
where the servers and other Information Technology rack equipment are mounted in a containment structure of the modular data center, where the modular data center, as assembled, with a HVAC unit attached to an end wall, is assembled as a shippable unit to the site of the data center as an integrated unit; and
cooling the servers and other Information Technology rack equipment using the HVAC unit mounted to the containment structure acting as an air-cooling unit to direct an air flow in a horizontal flow cycle around each row of servers and other Information Technology rack equipment.

13. The method of claim 12, further comprising:
directing the air flow to blow down a cold air aisle past the servers and other Information Technology rack equipment opposite a hot air aisle, which has hot air sucked away from the servers and other Information Technology rack equipment.

14. The method of claim 12, further comprising:
moving the air flow through an air director of the HVAC unit so that the air director sucks air from a hot air aisle and blows air to a cold air aisle for the servers and other Information Technology rack equipment.

15. The method of claim 13, wherein the modular data center can contain the set of servers and other Information Technology rack equipment in the containment structure, along with wiring, piping, and the HVAC unit, which all were assembled at a module assembly and factory site, and
where a first modular data center is adjoined and abutted to a second modular data center to form a single larger data center.

16. The method of claim 12, further comprising:
controlling humidity for the air flow with a heating coil integrated into the air-cooling unit.

17. The method of claim 12, further comprising:
removing particulates from the air flow with an air filter integrated into the air-cooling unit.

18. The method of claim 12, further comprising:
integrating the set of servers and other Information Technology rack equipment into an air dam integrated into the containment structure.

19. A heating/ventilation/air-condition (HVAC) unit, comprising:
a mounting structure to attach to an end wall of a containment structure of a modular data center to allow the HVAC unit to act as a cooling source;
a negative pressure compartment to suck in air from a return air aisle of an air flow in the containment structure via a return vent in the containment structure;
a heating coil to control humidity for the air flow within the containment structure; and
a positive pressure chamber to blow cold air into the supply air aisle via a supply vent of the containment structure, where the positive pressure chamber is set level with the negative chamber to facilitate a horizontal air flow around a set of servers and other Information Technology rack equipment within the containment structure, where the modular data center, as assembled, with the HVAC unit attached to the end wall, is assembled as a shippable unit to a site of a data center as an integrated unit.

20. The HVAC unit of claim 19, further comprising:
an air filter to remove particulates from the air flow.
